(19) United States
(12) Patent Application Publication
(10) Pub. No.: US 2025/0072165 A1
(43) Pub. Date: Feb. 27, 2025

(54) Aerosol Jet Printed Quantum Dot Matrix

(71) Applicant: Wisconsin Alumni Research Foundation, Madison, WI (US)

(72) Inventors: Joseph Andrews, Madison, WI (US); Anna Meredith, Long Beach, CA (US)

(21) Appl. No.: 18/236,640

(22) Filed: Aug. 22, 2023

(51) Int. Cl. H01L 33/04

(52) U.S. Cl. CPC H01L 33/04

(57) ABSTRACT

An aerosol jet printer is used to deposit freestanding quantum dot matrices over optical elements such as LEDs or photodetectors. The printing process avoids the need for photolithographic masks while allowing variation in matrix height to be obtained. The matrices may be assembled with no or little binder material.

### BACKGROUND OF THE INVENTION

The present invention relates to aerosol jet printing and in particular to an aerosol jet printing system for producing high aspect ratio quantum dot matrices.

Quantum dots are nanometer-sized semiconductors with optical properties that result from a combination of their small size and quantum mechanical effects. In one important application, quantum dots may operate as down-converters, excited by a first higher frequency of light into photoluminescence to emit a second lower frequency narrowband light.

This feature of quantum dots may be used, for example, in producing a color television-type display in which individual blue LEDs associated with display subpixels (red, green, or blue) are overlaid with quantum dots down converting the blue light into red, green, or blue light respectively. This feature of quantum dots may also be useful in producing color image sensors in which the quantum dots provide a narrowband filtering of light received by broadband photo detecting elements such as photodiodes, CMOS detectors, or CCD detectors.

In one manufacturing technique, a substrate containing an array of optical elements such as LEDs or photos sensors may be coated with an ink including quantum dots applied using an aerosol jet printer. The bell-shaped profile of the printed ink on the substrate limits the ability to obtain the high light-conversion efficiency over the entire area of the optical element.

For this reason, a photo lithographic mask may be applied before printing, the mask including openings over each optical element. The printing process is then used to fill selected openings with an ink of quantum dots of the appropriate color. The mask contains and supports a desired thickness of the liquid ink over the optical element prior to drying.

### SUMMARY OF THE INVENTION

The present inventors have determined that by extracting the solvent necessary to provide an aerosolizable quantum dot ink, during the time that the droplets are in-flight, assemblies of quantum dots may be printed having a substantially uniform height without a constraining photolithographic mask. Eliminating this mask greatly simplifies manufacture, reduces material waste, and allows of the thickness and profile of the quantum dot matrix to be varied on a matrix by matrix basis to maximize the light output of different quantum dots associated with different colors. The process eliminates or greatly reduces the need for a binder, improving the printing density, conversion efficiency, and further lowering material costs.

More specifically, in one embodiment, the invention provides an optical array having a set of electro-optical semiconductors arranged along a substrate and having an optically active area. A set of freestanding quantum dot matrices are positioned over the optically active area of the electro-optical semiconductors, the matrices comprised of subsets of different quantum dots associated with different electro-optical semiconductors and having different emission characteristics. The quantum dot matrices have a height of at least 5 μm and a cross-sectional area along a narrowest dimension of the active area that is at least 60% of the cross-sectional width times the cross-sectional height.

It is thus a feature of at least one embodiment of the invention to provide an optical array with substantially uniform thicknesses that can be produced using aerosol jet printing. Controlled evaporation of the solvent (the solvent being necessary for aerosolizing the ink) is performed during transit of the ink to the substrate to provide sufficient adhesion with greatly reduced post-printing spread.

The freestanding quantum dot matrices may include less than 0.1% by weight of a binder material.

It is thus a feature of at least one embodiment of the invention to eliminate or reduce the solvent necessarily associated with binder material.

The matrices maybe separated from each other by open gaps.

It is thus a feature of at least one embodiment of the invention to provide an optical array eliminating the need for a lithographic mask for corralling the quantum dots, thus reducing manufacturing costs and allowing assembly on curved surfaces that are not amenable to photolithographic techniques.

The average heights of the freestanding quantum dot matrices between different subsets may differ by greater than 10%.

It is thus a feature of at least one embodiment of the invention to permit tailoring of the height of the quantum dot matrices to the conversion efficiencies of the quantum dots used for different sub-pixels.

The substrate may have a curved surface so that different quantum dot matrices extend along nonparallel axes according to the curved surface.

It is thus a feature of at least one embodiment of the invention to provide curved displays using quantum dot matrices.

These particular objects and advantages may apply to only some embodiments falling within the claims and thus do not define the scope of the invention.

### BRIEF DESCRIPTION OF THE DRAWINGS

FIG. 1 is a perspective block diagram of an aerosol jet printer suitable for use with the present invention showing the location and orientation of three different cameras positioned with respect to an aerosol nozzle for monitoring the print jet and printed line and a central controller controlling multiple elements of the printer including ink temperature and carrier gas and sheath gas flow;

FIG. 2 is a simplified cross-sectional view of the atomizer and print nozzle of FIG. 1 showing the path of carrier gas and sheath gas;

FIG. 3 is a top plan view of an optical array, being either a display or sensor, showing an array of pixels divided into sub-pixels of different colors;

FIG. 4 is an elevational side view of a pixel of FIG. 3 showing placement of quantum dot matrices on top of optimal elements; and

FIG. 5 is a schematic representation of a printer system for curved televisions rendered practical by the present invention.

### DETAILED DESCRIPTION OF THE PREFERRED EMBODIMENT

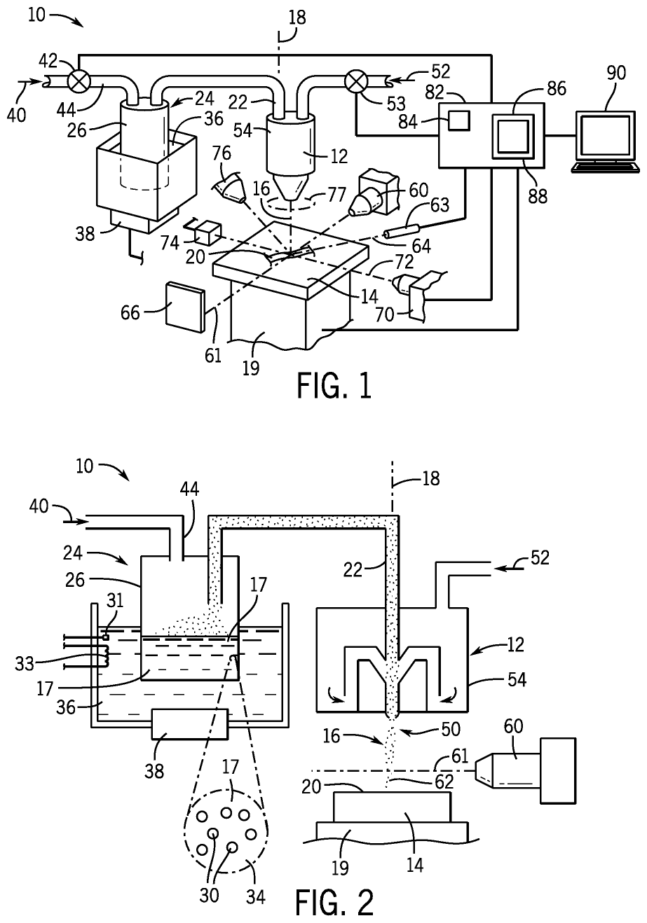

Referring now to FIG. 1, an aerosol jet printer 10 may include a print head 12 positioned above a substrate 14 on which material will be printed using a jet 16 of aerosolized quantum dot ink 17. The aerosolized quantum dot ink 17 is directed from the print head 12, generally along an axis 18 perpendicular to the broad extent of the substrate 14, while motion between the substrate 14 and the print head 12 is provided, for example, by an x-y-z table 19. A print head 12 suitable for the present invention is commercially available under the trade name Aerosol Jet 200 commercially available from Optomec of New Mexico, USA.

The x-y-z table may be of conventional design incrementally moving the substrate 14 controllably in three Cartesian axes having a z-axis aligned with axis 18, for example, using stepper or servo motors. This relative motion allows the jet 16 of aerosolized quantum dot ink 17 to paint lines 20 on the substrate 14 describing arbitrary shapes and areas in two dimensions and, by building up material in multiple layers, arbitrary volumes in three dimensions.

Referring also to FIG. 2, the print head 12 provides a central lumen 22 generally aligned along axis 18 that may receive aerosolized quantum dot ink 17 from an atomizer 24, for example, the latter being a pneumatic atomizer or an ultrasonic atomizer as shown.

The ultrasonic atomizer provides a reservoir 26 holding a quantum dot ink 17 generally comprised of quantum dots 30 in a suspending solvent 34. Non-limiting examples of quantum dot ink 17 include CdSe/CdZnS (core-shell) quantum dots 30 in toluene solvent 34 with an emission wavelength of 620 nm and CdSe/ZnS (core-shell) quantum dots 30 in toluene solvent 34 with an emission wavelength of 620 nm, both commercially available from Sigma-Aldrich of Darmstadt, Germany. These quantum dot inks 17, for example, at a concentration of 100 mg/mL may be mixed with terpineol (at 5 v/v %) to adjust viscosity as needed. Both toluene and terpineol are sufficiently volatile to fully evaporate from the quantum dot matrices to be produced, and thus may be distinguished from a binding material not used in the present invention such as would be expected to persistently bind the quantum dots together to form a matrix thereabout.

Generally different quantum dots (e.g., having different dimensions) are used to provide emissions in narrowband visible red, green, and blue frequencies. Narrowband emissions may have a bandwidth with a full width half maximum (FWHM) of less than 100 nm and typically less than 50 nm.

The reservoir 26 may be immersed, for example, in a water bath 36 coupling the quantum dot ink 17 acoustically with the ultrasonic transducer 38 serving, when the transducer is active, to generate a mist of aerosolized quantum dot ink 17 above the surface of the non-aerosolized quantum dot ink 17. A carrier gas 40, such as nitrogen, controlled by a valve 42 is introduced into the reservoir 26 through an inlet 44 that suspends and scavenges the aerosolized quantum dot ink 17 and carries it down the central lumen 22 toward an exit orifice of print nozzle 50 of the print head 12.

The water bath 36 may communicate with a thermocouple or other temperature sensor 31 and a temperature control element 33 allowing control of the water temperature bath and hence the temperature of the quantum dot ink 17. The temperature control element 33 may be a resistive heater or a Peltier device providing heating or cooling.

A sheath gas 52, such as nitrogen, controlled by a valve 53, may be introduced into a deposition head 54 around the central lumen 22 of the print head 12 to create a coaxial sheath of gas passing out of the exit orifice of the print nozzle 50 of the print head 12 in a ring around the aerosolized quantum dot ink 17 to focus the jet 16. Generally, the ratio of the volume of the sheath gas 52 to the carrier gas 40 defines a focus ratio which may be adjusted by adjusting the volume flow of each of the carrier gas 40 and the sheath gas 52. As will be discussed below, the focus ratio may be adjusted substantially to remove the solvents 34 from the quantum dots 30 prior to striking the substrate 14.

A high-speed, high-resolution droplet imaging camera 60 having an optical axis 61 parallel to and positioned above the printed surface of the substrate 14 allows imaging of the jet 16 sufficient to freeze and resolve the individual droplets of the aerosolized quantum dot ink 17 in rapidly acquired sequential images. The optical axis 61 is generally perpendicular to axis 18, and a focal plane 62 of the camera 60 provides sufficient depth of field to fully encompass the jet 16.

A laser 63 is positioned to direct a beam of light 64 in a frequency range of the camera 60 at an angle to the optical axis 61 of the imaging camera 60 to illuminate the jet 16 and its individual particles through backscatter. The laser 63 may be pulsed to “freeze” the droplets in the image in the manner of a stroboscope, allowing a wide variety of CCD type cameras to obtain successive images spaced apart by a few microseconds so that two images of a set of droplets at different times can be obtained within the field of view of the camera 60. The laser 63 and the camera 60 together provide a camera system producing the necessary images, although the invention contemplates other camera systems, for example, having continuous illumination and high-speed shutters or the like. For improved contrast, a light-absorbing background 66 may be placed opposite the camera 60 along the optical axis 61 and across the substrate 14.

An optional particle-loading camera 70 may be positioned to have an optical axis 72 orthogonal to the axis 61 to receive light from, for example, an infrared backlight 74. The particle loading camera 70 has a resolution in time and space comparable to camera 60 and is used for measuring light absorption by the droplets of the jets 16 to deduce particle loading, that is, the amount of quantum dots 30 in the droplets 32.

A third optional print imaging camera 76 may be directed generally downwardly to the substrate 14 to provide imaging of the print line 20 for assessing that line quality as will be described below. Illumination for the third imaging camera 76 may be provided by a ring light 77 or the like centered about axis 18 to provide even illumination to the printed surface of the substrate 14.

A controller 82 having at least one processor 84 communicates with an electronic memory 86 holding a stored program 88, as will be discussed in more detail below, and operating to control the various components of the printer 10. The controller 82 may communicate with a control terminal 90, for example, including a graphic control screen, keyboard, mouse and the like, allowing for user input and output as is generally understood in the art.

The controller 82 may receive signals from process sensors including the cameras 60, 70, and 76 (in the form of sequential image frames) as well as from the temperature sensor 31. In addition, the controller 82 may provide signals to control process variables, for example, the flow rate of the carrier gas 40 and sheath gas 52 (via valves 42 and 53) as well as the temperature control element 33. In addition, the controller 82 may provide control signals to the laser 63 and infrared backlight 74 for turning them on and off and signals to the x-y-z table 19 to maneuver it during the printing process to provide the desired print.

Generally, the controller 82 will execute the program 88 to conduct two separate tasks. The first task is that of reading a data print file describing a volume or area to be printed and providing control signals to the x-y-z table 19 to sequentially align different portions of the substrate with the jet 16. At each location, the computer controls the jet 16, for example, by modulating the carrier gas 40 and sheath gas 52, to print quantum dots 30 after removing most of the solvent 34 from the quantum dot ink 17 during flight and to selectively deposit quantum dots 30 on the substrate 14 in the desired pattern for the desired number of layers.

A second task may be conducted simultaneously with the first task or periodically and serves to adjust the operation of the printer to control the print line 20 with respect to desired line width, desired line density and consistency, line edge smoothness, and reduced overspray and post printing flow.

Further operating details and description are provided in U.S. patent application Ser. No. 17/404,345 filed Aug. 17, 2021, naming the assignee of the present application and hereby incorporated in its entirety by reference.

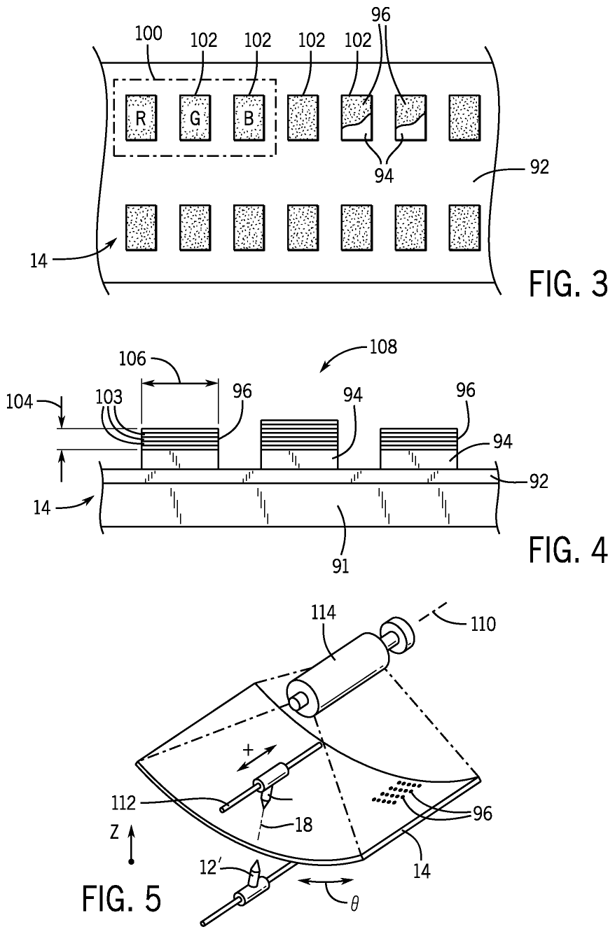

Referring now to FIGS. 3 and 4, the substrate 14 may provide a support layer 91 having on its upper surface a connection layer 92 comprised of an integrated array of thin film transistors and interconnections between attached optical elements 94 such as light emitting diodes, or light sensor such as CCD sensors, CMOS sensors, photodiodes or the like whose fabrication and interconnection into arrays is generally understood in the art. In the case of a display, the optical elements 94 may all be identical blue-green LEDs having substantially identical turn on voltages for convenient control.

Positioned on top of each optical element 94 is a quantum dot matrix 96 printed in self-supporting form by the above-described printer. Aerosol jet printing of a self-supporting quantum dot matrix 96 is possible by proper reduction of the solvent 34 in the ink 17 during flight and further assisted by eliminating binding material (e.g., to zero or less than 0.1% by weight) and the additional solvent necessary to lower the viscosity of such binding materials. A binding material can be understood to be a material other than the quantum dots 30, that is, effectively nonvolatile and thus retained indefinitely within the quantum dot matrix 96.

The optical elements 94 may be arranged in rows and columns and grouped in groups of three to form pixels 100, each pixel 100 thus having three sub-pixels 102 associated with individual optical element 94. Sequential sub-pixels 102 will use different colors of quantum dots 30 (i.e. having different photoluminescent frequencies) in the overlying matrix 96. For example, different sets of quantum dots 30 may have, respectively, frequencies centered within red, green, and blue portions of the visible spectrum.

Prior to printing, the optical elements 94 may be briefly treated with ultraviolet ozone to increase surface energy and material adhesion.

During printing, the carrier gas 40 and sheath gas 52 are adjusted in a closed loop with monitoring of the in-flight particles of quantum dots 30 so that the quantum dot matrices 96 may be built up in multiple layers 103 to a height 104 above their supporting optical element 94, with this height typically being eight to −12 μm.

The self-supporting nature of the matrices 96 allows a natural gap 108 (for example, less than 20 μm) between matrices 96 during printing and eliminates the need for a lithographic mask to separate the matrices 96 during printing.

By using the self-supporting printing approach, the height 104 of the optical matrices 96 above the optical element 94 may be varied for different sub-pixels 102 to reflect the conversion efficiencies of the respective quantum dots 30 optimizing light conversion. More generally, the quantum dot matrices 96 may provide for a fill factor, being an elevational cross-sectional area along a narrowest dimension 106 of the optical element 94 divided by the width times the height of this cross-section, and thus a measure of how rectangular the cross-sectional area is, of greater than 50% and typically greater than 80% when assembled from multiple printed layers 103 to at least 5 μm in height 104. Typically, the number of printed layers 103 will vary from 20 to 30 and will be greater than 2. More generally, the fill factor may be greater than 60% or greater than 70%.

Each layer 103 may, for example, be greater than 4 μm in thickness and may have a width of less than 35 μm and in some cases less than 20 μm or less than 15 μm.

The in-flight imaging system described above may be used to determine droplet density per unit length in the vertical direction and the corresponding velocity of the droplets and thus the total number of droplets that flow out of the nozzle 50 per unit time. This calculated flow rate can be compared to the number of droplets impinging on the substrate per unit time as verification and both factors can be used to control the operation of the printer through empirically derived relationships to permit the self-supporting printing of the quantum dot matrices 96.

In this regard, focus ratios of the carrier gas 40 and sheath gas 52 help remove solvent 34 from the quantum dots 30 in the droplets 32 and can reduce the column width of the printed droplets 32 promoting high-resolution printing, up to a point where the removal of solvent 34 creates greater line widths because a reduction in droplet mass reduces the ability of the droplets to follow the flow field of the carrier gas 40 and sheath gas 52. Dryer droplets 32 can also undesirably reduce the likelihood of droplets adhering to the substrate upon initial impact. Nevertheless, the dryer droplets permit steeper profiles of matrices 96 to be created.

In one nonlimiting example, a sheath gas flow rate of 60 and a carrier gas flow rate of 15 maybe used respectively with a nozzle diameter 100 μm. The standoff distance between the nozzle 50 and the substrate 14 may be approximately 3 mm. Ideally, the print speed is adjusted to allow a constant stream of material to be deposited while permitting an adequate dwell time during which evaporation of the remaining solvent can take place while minimizing the time during which there is sufficient solvent for the material to begin to spread.

Referring now to FIG. 5, the present invention provides the ability to readily assemble quantum dot matrices 96 on a curved substrate 14, for example, being a portion of a cylindrical wall about a central axis 110 for making curved television displays or the like. The XYZ table of FIG. 1 may be changed to an XZθ table where a conventional mechanical carriage 112 moves the print head 12 along an extra action parallel to the axis 110 and toward and away from the axis 110 along a Z direction.

The substrate 14 may be rotated about a pivot 114 coaxial with the axis 110 by a stepping motor or the like to provide printing over the entire curved surface, a process that would be difficult with photolithographic techniques. This relative motion allows the jet 16 of aerosolized quantum dot ink 17 to paint lines 20 on the substrate 14 describing arbitrary shapes and areas in two dimensions and, by building up material in multiple layers, arbitrary volumes in three dimensions. Printing on the external side of the curved surface may also be performed simply by inverting the location and orientation of the print head 12 to 12′ as indicated. It will be appreciated that this process can be used on any irregular surface including one curved in two dimensions or having irregular curvature limited only by the ability to place the optical elements 94. In cases where the substrate is manufactured in a flat state and then curved, the gaps 108 shown in FIG. 4 may relieve stresses caused by the curvature on the quantum dot matrices 96.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When introducing elements or features of the present disclosure and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the method steps, processes, and operations described herein are not to be construed as necessarily requiring their performance in the particular order discussed or illustrated, unless specifically identified as an order of performance. It is also to be understood that additional or alternative steps may be employed.

References to “a microprocessor” and “a processor” or “the microprocessor” and “the processor,” can be understood to include one or more microprocessors that can communicate in a stand-alone and/or a distributed environment(s), and can thus be configured to communicate via wired or wireless communications with other processors, where such one or more processor can be configured to operate on one or more processor-controlled devices that can be similar or different devices. Furthermore, references to memory, unless otherwise specified, can include one or more processor-readable and accessible memory elements and/or components that can be internal to the processor-controlled device, external to the processor-controlled device, and can be accessed via a wired or wireless network.

It is specifically intended that the present invention not be limited to the embodiments and illustrations contained herein and the claims should be understood to include modified forms of those embodiments including portions of the embodiments and combinations of elements of different embodiments as come within the scope of the following claims. All of the publications described herein, including patents and non-patent publications, are hereby incorporated herein by reference in their entireties.

To aid the Patent Office and any readers of any patent issued on this application in interpreting the claims appended hereto, applicants wish to note that they do not intend any of the appended claims or claim elements to invoke 35 U.S.C. 112(f) unless the words “means for” or “step for” are explicitly used in the particular claim.

What we claim is:

1. An optical array comprising:
a set of electro-optical semiconductors arranged along a substrate and having an optically active area; and
a set of freestanding quantum dot matrices positioned over the optically active area of the electro-optical semiconductors, the matrices comprised of subsets of different quantum dots associated with different electro-optical semiconductors and having different emission characteristics, wherein the quantum dot matrices have a height of at least 5 μm and a cross-sectional area along a narrowest dimension of the active area that is at least 60% of the cross-sectional width times the cross-sectional height.

2. The optical array of claim 1 wherein the freestanding quantum dot matrices include less than 0.1% by weight of a binder material.

3. The optical array of claim 1 wherein the average height of the freestanding quantum dot matrices between different subsets differs by greater than 10%.

4. The optical array of claim 1 wherein the substrate has a curved surface so that different quantum dot matrices extend along nonparallel axes according to the curved surface.

5. The optical array of claim 1 wherein the different emission characteristics of the subset include narrowband red emissions, narrowband blue emissions, and narrowband green emissions.

6. The optical array of claim 1 wherein the electro-optical semiconductors are selected from the group consisting of:
(1) light emitting diodes and wherein the optical array provides a display, and
(2) light detectors wherein the optical array provides an image sensor.

7. The optical array of claim 6 wherein the light emitting diodes are identical blue-green LEDs.

8. The optical array of claim 1 wherein the quantum dot matrices have a height of at least 4 μm and a cross-sectional area along a narrowest dimension of the active area that is at least 75% of the cross-sectional width times the cross-sectional height.

9. A method of producing an optical array having a set of electro-optical semiconductors arranged along a substrate and a set of quantum dot matrices positioned over the electro-optical semiconductors, the method comprising the steps of:
positioning a set of electro-optical semiconductors on a substrate;
aerosolizing an ink of quantum dots and solvent material to form an aerosolized jet of ink directed toward the substrate to form a set of layers spaced in time by a drying interval; and
controlling the aerosolized jet to remove solvent prior to impact with the electro-optical semiconductors to deposit a matrix of quantum dots having different emission characteristics over the electro-optical semiconductors to a height of at least 5 μm and with cross-sectional area along a narrowest dimension of the active area that is at least 60% of the cross-sectional width times the cross-sectional height.

10. The method of claim 9 wherein the aerosol jet printing uses an ink having less than 0.1% by weight of a binder material.

11. The method of claim 9 including the step of monitoring droplet velocity in flight to control a relative sheath gas and carrier gas flow rate.

12. The method of claim 9 wherein the substrate is free from masking around the optical elements having openings defining the matrices.

13. The method of claim 9 wherein aerosol jet printing is controlled to provide matrices of different emission characteristics with different corresponding different heights.

14. The method of claim 9 wherein the aerosol jet printing uses a printer head and controls the printer head to follow a curved surface of a substrate so that different quantum dot matrices extend along nonparallel axes according to the curved surface.

15. The method of claim 9 wherein the aerosolized jet is controlled to remove solvent prior to impact with the electro-optical semiconductors to deposit a matrix of quantum dots having different emission characteristics over the electro-optical semiconductors to a height of at least 5 μm and with cross-sectional area along a narrowest dimension of the active area that is at least 70% of the cross-sectional width times the cross-sectional height.
